(19) United States
(12) Patent Application Publication
(10) Pub. No.: US 2026/0135060 A1
(43) Pub. Date: May 14, 2026

(54) BROAD ION BEAM DELAYERING APPARATUS WITH INTEGRATED IMAGING

(71) Applicant: Denton Vacuum, LLC, Moorestown, NJ (US)

(72) Inventors: Kyle Godin, Moorestown, NJ (US); Anthony Githinji, Sterling, VA (US); David C. Douglass, Moorestown, NJ (US); Frank M. Cumbo, Moorestown, NJ (US)

(73) Assignee: Denton Vacuum, LLC, Moorestown, NJ (US)

(21) Appl. No.: 18/945,822

(22) Filed: Nov. 13, 2024

(51) Int. Cl. H01J 37/20; H01J 37/18; H01J 37/28; H01J 37/305

(52) U.S. Cl. CPC H01J 37/20; H01J 37/18; H01J 37/28; H01J 37/3053; H01J 2237/1825; H01J 2237/202; H01J 2237/2814; H01J 2237/30405

(57) ABSTRACT

The present invention, as manifested in one or more aspects, provides a novel apparatus, system and method for performing delayering and imaging of integrated circuit chips (IC). The delayering of the IC (also referred to as “etching” of the IC) followed by the imaging of the IC with the use of an electron microscope, for example, occur in one vacuumized chamber without breaking vacuum. Consequently, the likelihood of contamination is reduced and the overall time for IC delayering and evaluation is decreased.

### FIELD

The present invention relates generally to integrated circuit (IC) delayering, and, more particularly, to techniques for integrating imaging functionality with broad ion beam delayering.

### BACKGROUND

Within the semiconductor industry, it is often desirable to deconstruct or deprocess wafer-level integrated circuit chips or IC chips. This deconstruction process is advantageous in order to conduct failure analysis, yield improvement, and reverse engineering of the internal structure of the IC device, among other applications. IC chips are generally small devices which may have an area size of about 4 millimeters (mm)×4 mm or larger with dimensions up to about 25 mm×25 mm. The ICs commonly use a silicon substrate as a base where circuit devices such as transistors may be defined through ion implantation, and upon which layers of electronic materials (e.g., semiconductors, metals, etc.) are grown or deposited and patterned to form interconnected components in microelectronic circuits. These layers can be nanometers to micrometers in thickness and comprise a complex array of conductive metals, insulating dielectrics and/or semiconductor materials.

Industrial demand to analyze the failure mode or reverse engineer these complex IC structures requires the various layers to be precisely and uniformly exposed. Due to the inherent construction of the IC chip, the layers which are typically exposed first are the back-end-of-line (BEOL) and packaging layers furthest from the substrate. Then, to reach deeper layers of the IC, the layers are sequentially removed layer-by-layer, working down to the front-end-of-line (FEOL) layer. This removal technique is generally referred to as IC delayering or etching. The terms “etching” and “delayering” as used in this application are understood to have the same meaning and are used interchangeably.

With semiconductor device dimensions continuously scaling down and increasing complexity in ICs, delayering is becoming increasingly challenging. The primary goal of delayering in semiconductor failure analysis is to successfully remove layers of material in order to locate and identify an area(s) of interest. Several of the top-down IC delayering techniques include wet chemical etching, dry reactive ion etching, top-down parallel lapping (including chemical-mechanical polishing (CMP)), and ion beam and laser delayering techniques.

In general, an objective in the delayering process is to remove material in a manner which exposes the constituent layers in a common plane of the IC chip, which is usually parallel to the substrate plane. A failed delayering step would penetrate adjacent layers, thereby revealing material and structures not relevant to the plane of interest. This could be due to delayering to a plane not parallel to the substrate, due to creation of holes or voids, uneven removal due to material differences, or spatial variation of delayering across the substrate. The delayering process techniques need to be adept at creating a common planar surface which is smooth and uniform. The challenge confronting delayering techniques is the scale at which it performs; it must control the accurate removal of micrometer, nanometer, and atomic levels of surface material. For some layers, the removal process must stop with an accuracy in nanometers. This challenge is compounded because it is often not a single well-identified material which is being removed, but rather the surface will typically consist of different materials. The unique properties of these materials make them behave differently when exposed to delayering processes. The removal characteristics of the materials differ by their natural properties. Therefore, delayering must employ various tactics to control removal rates while producing a flat, planar surface at the micrometer scale.

As a part of the delayering process, it is often necessary to perform imaging in order to precisely determine when an IC layer of interest has been fully exposed in order to avoid unintentionally removing adjacent layers in the IC chip structure. Particularly when using ion beam delayering, which is conducted in a vacuum chamber, the device must be removed from the vacuum environment (i.e., breaking vacuum after the delayering process) has ended in order to perform imaging. This approach, however, significantly increases the time required for IC chip delayering and can introduce contaminants (including exposure to air) into the delayering process, which is undesirable.

### SUMMARY

The present invention, as manifested in one or more aspects, provides a novel apparatus, system and method for integrating imaging and broad ion beam integrated circuit (IC) chip delayering to advantageously reduce the likelihood of contamination and decrease the overall time for IC chip delayering and evaluation. Using techniques according to aspects of the invention, a finished or semifinished IC chip, while disposed in a vacuumized environment, is delayered by broad ion beam etching and is then is imaged by scanning electron microscopy (SEM) or other imaging technique without breaking vacuum. In one or more aspects, the IC chip is delayered to a specific depth using in-situ Secondary Ion Mass Spectrometry (SIMS) or Optical Emission Spectroscopy (OES) to monitor which layer the etch has reached, and then the IC chip is imaged with the SEM. After imaging, the IC can then be re-etched to a new depth and re-imaged as part of an iterative etching/imaging process for IC evaluation, all performed without breaking vacuum.

In accordance with one aspect, an IC evaluation apparatus includes a combined integrated circuit etching tool and an integrated circuit imaging tool disposed in a vacuumizable chamber of the apparatus. The IC evaluation apparatus also includes a processor coupled to the tools, a vacuum pump coupled to the vacuumizable chamber, and to a non-transitory processor readable storage medium containing processor readable program code for operations to be performed by the processor whereby after integrated circuitry (IC) is disposed in the vacuumizable chamber, the processor operates the vacuum pump to vacuumize the chamber and operates the etching tool to perform etching of the integrated circuit followed by the processor operating the imaging tool to perform imaging of the etched integrated circuitry without breaking vacuum.

In accordance with another aspect of the invention, an IC evaluation apparatus having an apportioned vacuumizable chamber having a vacuum pump coupled thereto, and an integrated circuitry etching tool and an integrated circuitry imaging tool disposed in a first portion and a second portion respectively of the vacuumizable chamber. The IC evaluation apparatus further comprises a transport mechanism at least partly disposed in the first portion, the second portion, and a third portion of the vacuumizable chamber wherein the third portion of the vacuumizable chamber has a first opening and a second opening aligned with corresponding openings of the first and second portions of the vacuumizable chamber and whereby the processor is coupled to the tools, the vacuum pump of the vacuumizable chamber and to a non-transitory processor readable storage medium containing processor readable program code for operations to be performed by the processor.

The transport mechanism has a movable support structure on which an IC chip (or IC substrate) may be placed and fastened thereto. Thus, the transport mechanism may transfer an IC chip from one portion to another portion of the vacuumizable chamber. The processor operates a vacuum pump coupled to the chamber to vacuumize the entire chamber after integrated circuitry is disposed on the movable support structure of the transport mechanism and the processor operates the movable support structure of the transport mechanism to transfer the IC chip between the first and second portions of the vacuumizable chamber thus enabling etching of the IC chip followed by imaging of the IC chip without breaking vacuum.

In accordance with yet another aspect of the invention, an IC chip evaluation method comprising a processor coupled to a non-transitory computer readable storage medium for operating the etching and imaging tools. The method comprises positioning an IC chip in a chamber portion for delayering by the etching tool. The etching tool, which is activated by the processor, delayers (i.e., etches) the IC chip at a particular defined location on the surface of the IC chip. The particular defined location is typically situated relatively near an area of interest on the chip where it is suspected that damage may have occurred to integrated circuitry embedded in the IC chip. The defined location may be, for example, an area where abnormalities in or near the integrated circuitry may exist at a certain layer of the IC chip.

Two well known systems used to monitor the etching of the IC chip are the SIMS (Secondary Ion Mass Spectroscopy) and Optical Emission Spectrometer (OES), both of which are used for the same purpose. The etching tool stops the delayering process upon receiving a signal (i.e., an etchant signal) from an Optical Emission Spectrometer (OES) (or from the SIMS—as the case may be) indicating no further etching should be performed at the particular location being etched, and any further etching or delayering may damage integrated circuitry located within the IC chip or damage the layers on which they are positioned. The etchant signal may be received by the etching tool or by the processor. When the etchant signal is received by the processor, the etching is stopped by the processor controlling the operation of the etching tool.

As may be used herein, “facilitating” an action includes performing the action, making the action easier, helping to carry the action out, or causing the action to be performed. Thus, by way of example and not limitation, instructions executing on one processor for controlling one or more actions of an IC chip delayering system might facilitate an action carried out by instructions executing on a remote processor, by sending appropriate data or commands to cause or aid the action being performed. For the avoidance of doubt, where an actor facilitates an action by other than performing the action, the action is nevertheless performed by some entity or combination of entities.

Also, as may be used herein, the term “couple” refers to a mechanical or physical connection between two objects or a mechanical or physical connection between different points on different objects. The term “couple,” “coupled”, or “coupling” also may refer to a link such as a communication link or any link through which analog electrical signals, digital electrical signals, or optical signals are able to propagate through different media (e.g., air, vacuum, wires, waveguides and optical fibers). The signals may be wired signals or wireless signals and they can transfer or caused to be transferred from one device to another.

One or more aspects of the invention may be implemented in the form of a processor coupled to non-transitory processor readable storage medium containing processor usable program code for performing method steps for implementing at least a portion of the invention. Furthermore, one or more aspects of the invention or elements thereof can be implemented in the form of a system (or apparatus) including a memory, and at least one processor that is coupled to the memory and operative to perform exemplary method steps. Yet further, in another aspect, one or more aspects of the invention or elements thereof can be implemented in the form of means for carrying out one or more of the method steps described herein; the means can include (i) hardware module(s), (ii) software module(s) stored in a computer/processor readable storage medium and implemented on a hardware processor, or (iii) a combination of (i) and (ii); any of (i)-(iii) implement the specific techniques set forth herein.

Techniques according to aspects of the present invention are directed toward a technological improvement, or toward a solution to a technological problem, that can provide substantial beneficial technical effects, particularly in the field of IC chip evaluation. By way of example only and without limitation or loss of generality, one or more aspects of the invention provide enhanced techniques for IC chip evaluation, the aspects having one or more of the following advantages, among other important benefits:
uses broad ion beam etching which has low and tunable material selectivity, allowing for planar delayering
covers a large area with good uniformity and collimation, and can therefore delayer the entire IC chip uniformly;
combines the delayering and imaging functions into one tool, to process and then image several layers of an IC chip consecutively without breaking vacuum;
allows for the vacuumizing of all of the portions of a vacuumizable chamber followed by the delayering and then the imaging of an IC;
reduces overall IC chip delayering time for providing speedier failure analysis and/or reverse engineering;
reduces likelihood of contamination introduced into the IC delayering process.

These and other features and advantages of the present invention will become apparent from the following detailed description of illustrative aspects thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A is a cross-sectional view depicting a plurality of layers of at least a portion of an exemplary IC chip;

FIG. 1B is a graph depicting an exemplary output signal generated by an Optical Emission Spectrometer (OES), or other etchant material analysis tool, during etching of the illustrative IC chip shown in FIG. 1A;

FIG. 2 conceptually depicts at least a portion of an exemplary IC chip evaluation tool that integrates delayering and imaging functionalities, according to one or more aspects of the present invention; and

FIG. 2A depicts the IC chip evaluation tool with relatively high vacuum pumps added to the delayering and imaging functionalities of FIG. 2, and an optional load lock 234 is added to enable quick loading of an IC chip to be evaluated in a chamber of the tool without venting the chamber (i.e., chamber 204 or chamber 204 plus enclosure 207 and chamber 205).

FIG. 3 depicts another aspect of an exemplary IC chip evaluation tool that integrates delayering and imaging functionalities in one vacuumizable chamber whereby the imaging tool is positioned at a side of the vacuumizable chamber and an optional load lock mounted at the other side of the chamber to enable quick loading of the IC chip to be evaluated without venting the chamber.

FIG. 3A depicts yet another aspect of an exemplary IC chip evaluation tool that integrates delayering and imaging functionalities in one vacuumizable chamber with the imaging tool positioned directly opposite the delayering tool and a load lock attached to a side of the chamber for quick loading of an IC chip to be evaluated without venting the chamber.

FIG. 4 is a flow diagram depicting at least a portion of an exemplary method for performing IC evaluation, according to one or more aspects of the present invention.

It is to be appreciated that elements in the figures are illustrated for simplicity and clarity. Common but well-understood elements that may be useful or necessary in a commercially feasible aspect may not be shown in order to facilitate a less hindered view of the illustrated aspects.

### DETAILED DESCRIPTION

Principles according to aspects of the present invention will be described herein in the context of an illustrative apparatus, system and/or method for integrating broad ion beam integrated circuit (IC) chip delayering and imaging functionality into the same tool, advantageously reducing the likelihood of contamination and decreasing the overall time for performing IC evaluation.

In one or more aspects, an IC chip evaluation apparatus includes a broad ion beam etching tool for performing IC chip delayering and an imaging tool for performing IC evaluation (e.g., failure analysis or reverse engineering), housed in the same vacuum chamber. After imaging, the IC can then be re-etched to a new depth and re-imaged as part of an iterative etching/imaging process, all without breaking vacuum. It is to be appreciated, however, that the invention is not limited to the specific apparatus, system and/or methods illustratively shown and described herein. Rather, it will become apparent to those skilled in the art given the teachings herein that numerous modifications can be made to the aspects shown that are within the scope of the claimed invention. That is, no limitations with respect to the aspects shown and described herein are intended or should be inferred.

Several terms will be used throughout the present disclosure, the definitions of which are provided below.

Ion beam etching is a well-known method by which a plasma is generated (e.g., using radio frequency (RF) or direct current (DC)), and then positive ions are accelerated or allowed to drift towards a target or substrate; this is referred to as an ion beam. If the ions are above a prescribed minimum energy level, they will “sputter” or “etch” the substrate, generating a collision cascade which results in physically knocking atoms off the target material. The etch rate can be controlled through adjusting the angle between the ion beam and the substrate (tilt), heating or cooling the substrate, changing ion beam parameters (ion energy distribution or flux), or introducing a chemically reactive species. The chemically reactive species can be introduced through the source, to become part of the ion beam (reactive ion beam etching, RIBE), as a chamber background gas during etching, or near the substrate (chemically assisted ion beam etching, CAIBE).

An integrated circuit (IC) is a device which may include thousands or billions of interconnected semiconductor devices formed on a common substrate by locally altering the Fermi levels of the material via ion implantation, oxidation, or other IC fabrication methods. A plurality of electrical interconnect layers are built on top of the device layer. Everything is planar patterned; the design elements are placed over a two-dimensional area and then must be electrically connected to form the final device. Interconnect layers may be made of a metal, such as, but not limited to, tungsten, copper, titanium, aluminum and/or alloys of such metals, or polycrystalline silicon. In different IC chips, there may be only a few or up to 15 or more layers of interconnects. As the interconnect layers go up from the substrate, they increase in size, from a trace dimension of less than 10 nanometers (nm) up to 400 nm or more on the final layers.

Material selectivity refers generally to the difference in etch rates between different materials. The interconnect layers may be made of mixed materials, for instance copper and tungsten, and are separated by an insulating filler, such as silicon dioxide. To uniformly delayer the substrate, these materials must be etched at the same rate. The ion beam is usually a chemically inert gas, such as argon. However, even without chemical interaction, the etching process is materially-dependent because it is dependent on the size of the nucleus, the strength of the electronic bonds, and the structure of the material being etched (e.g., crystalline, amorphous, or something in between). Low selectivity is when two different materials etch at relatively similar rates. Zero selectivity cannot be achieved in practice, but it can be reduced to an acceptable level by controlling the etch angle (tilt), ion energy, and/or by introducing chemically reactive species, such as, for example, oxygen or fluorine radicals via O₂, CF₄, or SF₆ (including RIBE, CAIBE, or as a background gas).

Scanning electron microscopy (SEM) is an imaging process that utilizes a beam of electrons focused down to a few-nm spot and directed towards a sample. These high energy electrons may either be reflected and collected (backscatter electrons), or they may eject electrons from the substrate which are collected (secondary electrons). The beam is rastered and the signal intensity as a function of position forms an image. Advantages of SEM over optical microscopy are extremely high resolution and extremely high depth of field.

Secondary ion mass spectroscopy (SIMS) is a process whereby an ion beam sputters the substrate and the ejected atoms are sometimes ionized, called secondary ions, the beam itself being the primary ions. The secondary ions are measured in a mass spectrometer to determine their atomic mass. Thus, SIMS produces a plot of atoms in the substrate versus time as etching is performed, essentially providing a depth profile of the substrate. It can be calibrated to give actual values for atomic concentration. As SIMS is utilized in conjunction with aspects of the invention, it is enough to have relative values to assist in determining when metal layers in an IC chip under evaluation start and stop.

Substrate, as the term is used herein, is intended to refer to the IC chip under evaluation.

Uniformity refers to a planarity of the substrate after being etched. Usually reported as a ratio of range/mean, as a percentage. By way of example only and without limitation or loss of generality, consider an IC chip wherein the center has a maximum thickness of 190 nm and a thickness at the edge is 195 nm, with the depth linearly connected between these two points. The uniformity of the IC chip can be determined as

$$\frac{[ range ]}{[ mean ]} = \frac{195 - 190}{\frac{195 + 190}{2}} = 0.026 = 2.6 \% .$$

Uniformity can also be reported as standard deviation (σ) over mean, the standard deviation of a line scan or an area scan. Range/mean approximately equals 3σ/mean.

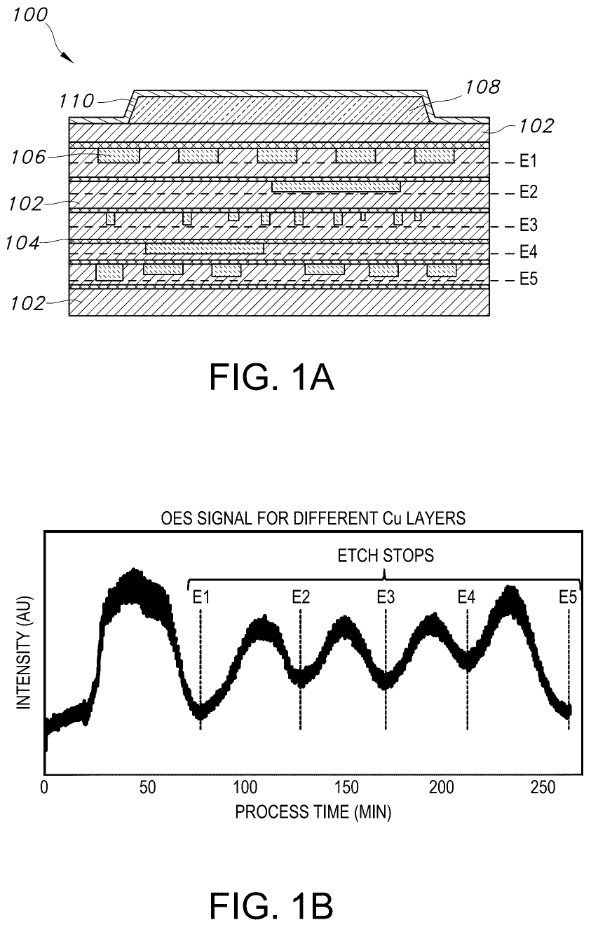

FIGS. 1A and 1B conceptually depict an illustrative delayering process of an IC chip for which aspects of the invention are directed. Specifically, FIG. 1A is a cross-sectional view depicting at least a portion of an exemplary IC chip 100. The IC chip 100 includes a plurality of stacked dielectric layers 102 (e.g., silicon dioxide, etc.), each of the dielectric layers being separated from one another by an active layer 104, comprising, for example, doped amorphous silicon, polysilicon, silicon nitride, or another semiconductor material. Patterned metal layers 106 (e.g., copper, aluminum, etc.) are disposed in the dielectric layers 102 for forming electrical interconnections between circuits and/or components formed in the active layers 104 of the IC chip 100. A metal capping layer 108 (e.g., aluminum) may be formed on the top dielectric layer 102, and the IC chip 100 is then preferably covered with an encapsulation layer 110.

With continued reference to FIG. 1A, etch stops are shown, labeled E1 through E5, each of the etch stops indicating a desired location where an etching tool should stop the delayering process for imaging and evaluating the structures of a corresponding layer. The etching process can be monitored using a Secondary Ion Mass Spectrometer (SIMS), Optical Emission Spectrometer (OES), or other etchant material analysis tool. FIG. 1B is a graph depicting an exemplary output signal generated by the OES during etching of the IC chip 100 shown in FIG. 1A; the graph illustrates intensity in arbitrary units (au) as a function of process time in minutes (min). In FIG. 1B, spectral lines associated with the copper layers 106 are identified as a trend line. End points were set at the minima of the copper trend lines in order to analyze each layer by SEM. Each individual copper layer is distinguishable in every peak OES signal, with each valley of the OES signal indicating a desired etch stop (E1-E5) identified in FIG. 1A.

Using current state-of-the-art IC evaluation processes, delayering and imaging of an IC chip are performed in independent steps using separate tools. Thus, after delayering is performed on an IC chip using a standard delayering tool, the user is required to remove the IC chip from a vacuum chamber of the delayering tool and transfer the chip, in air, to a scanning electron microscope or other imaging tool for analysis. The process of transferring the IC chip under evaluation between delayering and imaging tools for performing delayering and analysis, respectively, is repeated until the IC evaluation process has been completed. This approach of separately performing delayering and imaging of the IC chip, transferring the IC chip back and forth in air, is both slow and undesirably increases the likelihood of contamination of the IC chip.

As previously stated, aspects of the invention advantageously integrate IC chip delayering and imaging functionalities into the same tool, performed without exposure to atmosphere. By combining the delayering and imaging functions into one tool, several layers of an IC chip can be consecutively processed and then imaged without breaking vacuum. In this manner, aspects of the invention beneficially reduce overall IC chip evaluation time and reduce the likelihood of contamination, thereby achieving a superior IC evaluation result.

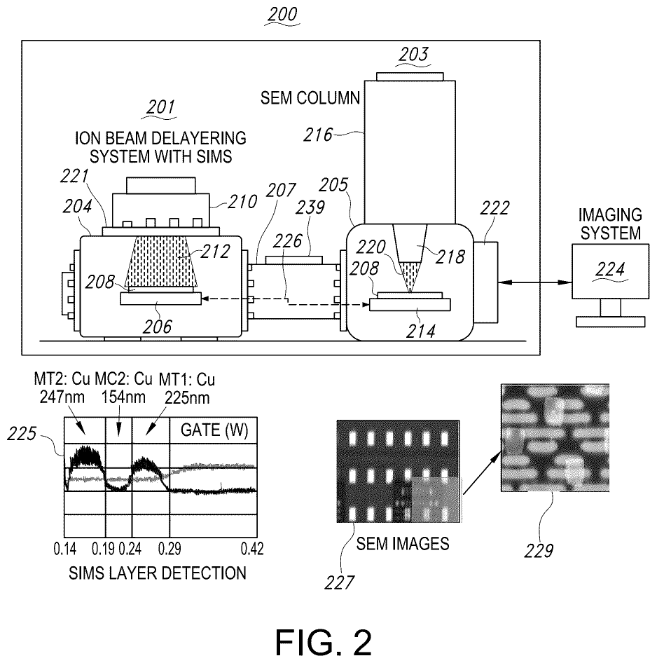

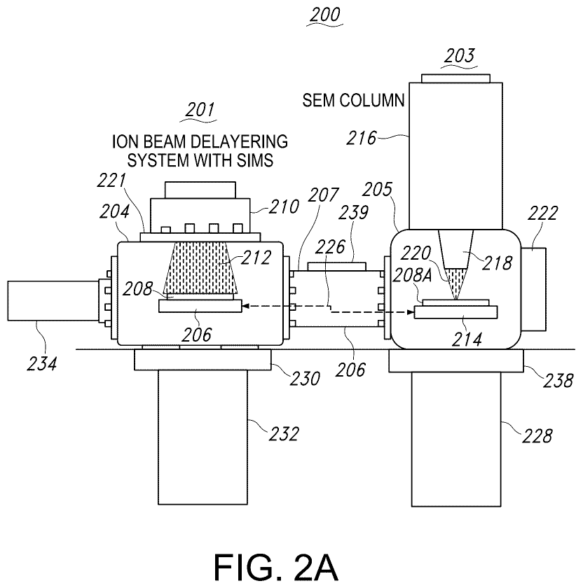

By way of illustration only and without restriction, FIG. 2 conceptually depicts at least a portion of an exemplary IC chip evaluation apparatus 200 that integrates delayering and imaging functionalities, according to one or more aspects of the invention. The IC chip evaluation apparatus 200 includes a vacuumizable chamber having portions 204, 207, and 205. The processor of the apparatus is coupled to shutter 221 and operates shutter 221 to prevent etching of the substrate 208 until the ion beam 212 is stable. The processor is also coupled to ion beam source 210, which is mounted on top of shutter 221, which is mounted on top of chamber 204. Ion beam source 210 generates ion beam 212 that passes through shutter 221 and then through an opening (not shown) at the top of chamber portion 204. Shutter 221 is coupled to the processor of the apparatus and shutter 221 is operated by the processor to block or pass the ion beam passing through the shutter 221. Prior to starting the etching process, the chamber portions (i.e., chamber 204, chamber enclosure portion 207 and chamber portion 205) are vacuumized to allow the start of the etching process as will be discussed with respect to FIG. 2A. Assuming the chamber portions have been vacuumized, the etching process is initiated by the processor activating ion beam source 210 resulting in the generation of ion beam 212 that ultimately impinges on IC 208 positioned on movable support structure 206 of transport mechanism 226. The processor may have started the etching process as a result of a command typed by a user of the apparatus or some type of switch used by a user of the apparatus. Shutter 221 is operated by the processor to make the etching start immediately and stop immediately thus avoiding instability at the start and at the end of the etching process. Also, shutter 221 helps to more accurately control the etching process.

When an ion beam 212 is being generated by the ion beam source 210, the ion beam passes through the shutter 221 and through the opening (not shown) at the top of chamber 204 and onto IC 208 positioned on movable support structure 206 (also called a “chuck”) of the transport mechanism 226. The IC 208 is etched until a signal (i.e., an etchant signal) is received by the apparatus 200 from a monitoring SIMS system or from a monitoring OES system in communication with apparatus 200 indicating that the desired layer, position between layers, or etch depth has been reached. The etchant signal is received by the apparatus 200. The control of the ion beam source 210 and the shutter may be done automatically by computer control signals generated by the processor based on machine vision, optical image recognition, and Artificial Intelligence (AI) programming. When the ion beam 212 passes through shutter 221, the opening (not shown) at the top of chamber 204, and impinges upon the surface of IC 208 exposed to the ion beam, the IC chip 208 is etched as desired.

IC 208 is positioned on movable support structure 206 of transport mechanism 226, which is at least partially disposed in chamber portions 204, 205, and enclosure portion 207. Enclosure portion 207, which is also referred to as vacuumizable enclosure portion 207, has an optional isolation valve 239. Transport mechanism 226 has a second support structure 214 shown disposed in chamber portion 205. At least part of Transport mechanism 226 is also disposed in vacuumizable enclosure portion 207. At least a portion 218 of imaging tool 203 is disposed in Chamber portion 205. At least part of transport mechanism 226 is disposed in Enclosure 207. Transport mechanism 226 is also partly disposed in chambers 205 and 204 as shown. Transport mechanism 226 has movable support structure 206 shown disposed in chamber 204 and movable support structure 214 shown disposed in chamber 205 along with at least part of imaging tool 203.

In one or more aspects of the IC evaluation apparatus 200, the movable support structures 206 and 214 may be the same structure. In such a circumstance, there would only be one support structure. In a case where there is only one support structure, the IC evaluation apparatus 200 would preferably have a transport mechanism 226, which may be implemented in the form of a rotating arm, conveyor, or other means as will become apparent to those skilled in the art. The IC chip 208 under evaluation in chamber 204 is positioned in chamber portion 204 for etching by the delayering tool 201. After the etching is stopped, the etched IC chip 208 under evaluation is then moved by the transport mechanism 226 to chamber 205 via enclosure 207 for imaging by the imaging tool 203 without breaking vacuum.

In a circumstance where there are two support structures (i.e., movable support structures 206 and 214 as shown in FIGS. 2 and 2A), the transport mechanism 226 activates both movable support structures to switch positions. Upon activation of the transport mechanism 226, movable support structure 206 is caused to move to chamber 205 and simultaneously movable support structure 214 is caused to move to chamber 204. Such a transfer would be called a two-way transfer when both support structures are populated with an IC 208 and IC chip 208A as shown. When only one of the support structures is populated with an IC chip, the simultaneous activation of both support structures would cause a transfer of an IC chip from a first chamber to a second chamber and no transfer of IC from the second chamber to the first chamber. Thus, different types of transfers of integrated circuitry between chambers 204 and 205 may be accommodated. That is, transfer of integrated circuitry from chamber 205 to chamber 204 is possible and transfer of integrated circuitry from chamber 204 to 205 is also possible. Such a “one-way transfer” requires that only one of the support structures be populated with an IC chip. A two-way transfer requires that both support structures be populated by different IC chips and that activation of both support structures would cause the ICs to switch positions. That is, upon activation of the transport mechanism an IC chip in chamber portion 205 would be transferred to chamber portion 204 and an IC chip formerly located in chamber 204 would be transferred to chamber 205. A specific design of the operation of the transport mechanism to perform one-way or two-way transfers may be different from the current transport mechanism or the current design may be used. A new design of the transport mechanism may be apparent to those experienced in the design of conveyor belts or other similar electrommechanical machines specializing in mechanical transfer of objects within a defined space. Such electromechanical machines transfer objects from one location to another location within a particular defined space with the aid of computer control signals, imaging techniques or the operation of such a machine may be manually controlled by a user.

Transporting of an IC between the delayering tool 201 and the imaging tool 203 during multiple iterations of the IC evaluation process may be performed, for example, with the aid of optical image recognition, machine vision, artificial intelligence (AI), computer control signals or other imaging techniques, or it may be performed manually by a user.

Still referring to FIG. 2, delayering tool 201 and movable support structure 206 of transport mechanism 226 are disposed in a first portion (chamber 204) of the vacuumizable chamber of IC evaluation apparatus 200. Imaging tool 203 and movable support structure 214 are disposed in a second portion (chamber 205) of the vacuumizable chamber of IC chip evaluation apparatus 200. A third portion of the vacuumizable chamber, i.e., enclosure 207, has an optional isolation valve 239 and is coupled to the first and second chambers as shown. Thus, part of both tools (201 and 203) are disposed within a portion of the vacuumizable chamber. Advantages of integrating the delayering tool 201 and imaging tool 203 in the same vacuum environment include providing a decreased overall IC evaluation time and a reduced likelihood of IC contamination primarily by eliminating the need to break vacuum each time the IC chip is imaged after having been delayered. OES or SIMS signals.

Images 227 (of circuits, devices and metal connecting layers) associated with an IC under examination (e.g., IC chip 208), are shown in FIG. 2. Image 229 is a closeup view of a portion of the images 227 shown. Also, the characteristics of an etchant signal from a SIMS monitoring device is shown at SIMS LAYER DETECTION 225 of FIG. 1.

The ion beam delayering tool 201, in one or more aspects, includes a substantially rigid movable support structure 206 of transport mechanism 226 partially disposed in chamber 204 wherein at least a part of movable support structure 206 of the transport mechanism 226 is disposed and adapted to receive and hold an IC wafer or device under test 208. Similarly, support structure 214 of transport mechanism 226 is disposed in chamber 205 and adapted to receive and hold an IC wafer 208A positioned directly under housing 218 (containing lenses and apertures) of imaging tool 203 as shown.

The imaging tool 203 in one or more aspects includes support structure 214 of transport mechanism 226, which is shown disposed in chamber 205 of imaging tool 203. An IC wafer 208 (i.e., IC chip) or device under test may be supported by support structure 214 in the same manner as movable support structure 206 shown disposed in chamber 204. Thus, the transport mechanism is positioned to transfer a device under test from chamber 204 to chamber 205. Also, a device under test can be transferred from chamber 205 to chamber 204 if necessary. The IC chip 208 or 208A may be removably attached to the movable support structure 206 (or to movable support structure 214 in the case of imaging the IC) using any known attachment means, including, for example, electrostatic mechanisms, clamping, and/or adhesives.

The ion beam delayering tool 201 is positioned in vacuumizable chamber 204 and further includes a highly directional ion beam source 210 configured to generate a broad ion beam 212 that is directed towards and focused on an upper surface of the IC 208 disposed on movable support structure 206. The ion beam 212, is used to physically remove material from the IC 208. To accomplish this, in one or more aspects, an inert gas is introduced to the ion beam source 210, is ionized to form the ion beam 212, which moves directionally towards the surface of the IC chip 208 with relatively high energy. The ions then strike the surface of the IC chip 208 and the resulting impact removes, or sputters, material from the IC chip 208. This method of etching provides high accuracy and precision through control of the ion beam energy by the ion beam source 210.

Broad ion beam etch (IBE) is utilized, in one or more aspects, to achieve uniform etch rates for multi-material layers over a large area of the IC 208. Broad ion beam also provides extremely low material selectivity compared to chemical etching techniques. However, it may still not be low enough for simply normal incidence of the beam onto the surface of the IC 208. Accordingly, in one or more aspects of the invention, material selectivity is further minimized by controlling an angle between the ion beam and the surface of the IC chip 208, introducing chemically reactive species to the delayering process (e.g., a source of oxygen or fluorine radicals), and/or controlling one or more ion beam parameters, primarily ion energy.

The imaging tool, 203 in one or more aspects, generates an electron beam 220 that impinges on IC wafer (or IC substrate, or IC chip) 208 positioned on a substantially rigid support structure 214 adapted to receive and hold the IC wafer 208 or 208A. Similar to the movable support structure 206 of the delayering tool 201, the movable support structure 214 in the imaging tool 203 may employ any known attachment means to hold the IC 208 in place, such as, for example, vacuum and/or electrostatic techniques, clamping, and/or adhesives. The imaging tool 203 further includes an SEM column configured to generate, through a series of lenses and apertures 218, a focused electron beam 220 with low energy dispersion for imaging the IC chip 208. More particularly, the imaging tool 203 in this illustrative aspect works by rastering the IC 208 with the electron beam 220. An electron gun (not shown) disposed at an upper end of the SEM column 216 generates and accelerates the electron beam, which is then conditioned for collimation, astigmatism, and energy dispersion in the SEM column as the electrons travel towards the target IC 208. During this action, the electron beam passes through a series of lenses and apertures within housing 218. This process occurs under vacuum conditions, which limits the molecules or atoms present in the SEM column or chamber 216 from interacting with the electron beam to ensure a high quality of imaging.

The electron beam 220 scans the IC 208 in a raster pattern, scanning the surface area in lines from side to side and/or top to bottom. The electrons in the electron beam 220 interact with atoms on the surface of the IC 208. This interaction creates signals in the form of secondary electrons, backscattered electrons, and x-rays that are characteristic of the surface of the IC 208 being imaged. Detectors 222 in the imaging tool 203 pick up these signals and create high-resolution images of the surface of the IC 208A that are displayed on an imaging system 224, such as a computer monitor or the like. Image data is transmitted from the imaging tool 203 to the imaging system 224 by way of a communication channel, either wired or wireless, established therebetween.

In one or more aspects, the support structure 214 associated with the imaging tool 203 and the movable support structure 206 associated with the delayering tool 201 may be the same. In such a scenario, the IC evaluation apparatus 200 preferably comprises a transport mechanism 226, which may be implemented in the form of a rotating arm, conveyor, or other means as will become apparent to those skilled in the art, for transporting the IC under test 208 from the delayering tool 201 to the imaging tool 203, via chamber 204, vacuumized enclosure 207 and chamber 205 so as to avoid breaking vacuum. Transporting of the IC 208 between the delayering tool 204 and the imaging tool 205 during multiple iterations of the IC evaluation process may be performed autonomously, for example with the aid of optical image recognition, machine vision, artificial intelligence (AI), computer control signals or other imaging techniques, or it may be performed manually by a user.

SEM is one technique that can be utilized as the imaging tool 203 to image features of the IC under test 208, in situ, with sufficient resolution and depth of field (e.g., features being about 5 nm to 1000 nm in size). It is to be appreciated, however, that aspects of the invention are not limited to SEM imaging. Rather, alternate imaging and analytical techniques may also be used, in accordance with one or more other aspects, including, but not limited to, x-ray photoelectron spectroscopy (XPS), electron energy loss spectroscopy (EELS), x-ray fluorescence (XRF), auger analysis, x-ray diffraction (XRD), infrared absorption, optical microscopy, and x-ray microscopy, among other techniques that will be known by those skilled in the art.

By way of illustration only and without restriction, FIG. 2A conceptually depicts at least a portion of an exemplary IC evaluation apparatus 200 that integrates delayering and imaging functionalities, according to one or more aspects of the invention. The IC evaluation apparatus 200 shown in FIG. 2A is identical in many respects to the IC evaluation tool of FIG. 2. FIG. 2A, however, depicts a high vacuum pump 232 coupled to chamber 204 via an isolation valve 230 and an opening (not shown) at the bottom of chamber 204. The vacuum pump 232 may be a cryogenic or a turbomolecular pump. Vacuum pump 232 may be mounted at the bottom of chamber 204 as shown. The vacuum pump 232 may also be mounted at the top, bottom, or at a side of chamber 204, or coupled to chamber 204 via ducts (not shown). When mounted at the top, side, or bottom of chamber 204, an isolation valve 230 may be placed between chamber 204 and high vacuum pump 232 as shown in FIG. 2A.

FIG. 2A depicts another vacuum pump 228, which operates in the same manner as vacuum pump 232, and is coupled to the bottom of chamber 205 via isolation valve 238 as shown and an opening (not shown). The vacuum pump 228 may also be mounted at the top, or at a side of chamber 205, or coupled to chamber 205 via ducts (not shown). When mounted at the top, side, or bottom of chamber 205, an isolation valve 238 may be placed between chamber 205 and high vacuum pump 228 as shown in FIG. 2A.

A load lock 234 may be coupled to chamber 204 to allow integrated circuits such as, for example, IC chip 208 to be loaded quickly through a side opening (not shown) of chamber 204 without venting chamber 204. Load lock 234 may have a door for loading an IC 208 at atmosphere onto a holder of some sort, a vacuum pump to pump down the load lock itself to a suitable pressure, a valve between load lock 234 and chamber 204, and a manipulator (either manual or automated) that allows the IC 208 to be placed on movable support structure 206 (or chuck 206) and fastened thereto. Movable support structure 206 (or chuck 206) may have none, one, or any subset of the following capabilities: heating with heating elements, bulbs, or hot water; cooling with water or He gas (Helium gas) or other suitable gas; and may be tilted relative to the ion beam source.

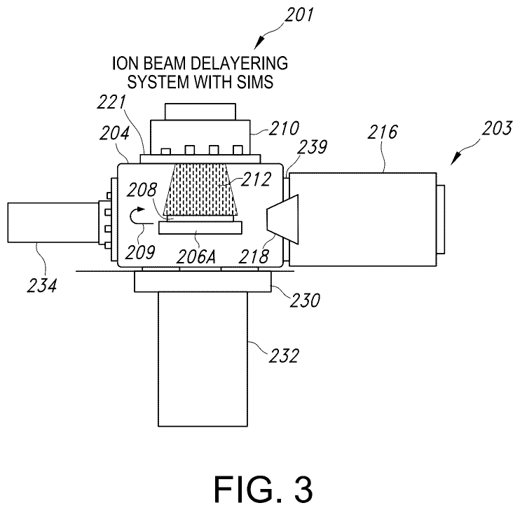

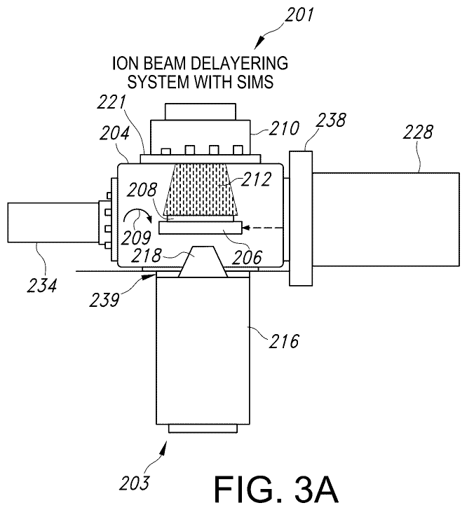

By way of illustration only and without restriction, FIG. 3 conceptually depicts at least a portion of an exemplary IC evaluation apparatus that integrates delayering and imaging functionalities according to one or more aspects of the invention. The Ion beam Delayering System 201 with SIMS (or OES) including ion beam source 210 is mounted at the top of vacuumizable chamber 204 and generates a highly directional ion beam 212 directed towards and focused on an upper surface of the IC chip 208 disposed on chuck 206. The ion beam 212 is used to physically remove material from the IC 208. In one or more aspects of the invention, an inert gas is introduced to the ion beam source 210 to form the ion beam 212, which moves directionally towards the surface of the IC chip 208 with relatively high energy. The ions then strike the surface of the IC 208 and the resulting impact removes, or sputters, material from the IC chip 208. This method of etching provides high accuracy and precision through the control of the ion beam energy by the ion beam source 210.

Continuing with the description of the IC evaluation apparatus of FIG. 3, chamber 204 has two side openings (not shown): a first side opening attached to load lock 234. Chamber 204 has a second opening (not shown) for attaching SEM column 216, and lens and apertures housing 218 to the other side of chamber 204 with lens and apertures 218 positioned within chamber 204 as shown. An optional isolation valve 239 may be positioned between SEM column 216 and chamber 204 as shown. A single baffle or a series of baffes or pinholes (not shown) may be created at the isolation valve 239 to maintain the imaging system at several orders of magnitude of lower pressure than chamber 204.

A high vacuum pump 232 is coupled to the bottom of chamber 204 with optional isolation valve 230 placed between high vacuum pump 232 and the bottom of chamber 204. The high vacuum pump 232 may be a cryogenic pump or a turbomolecular pump. The high vacuum pump 232 may be mounted at the bottom (at an opening—not shown), top, or side of chamber 204. Load lock 234 is coupled to one side of chamber 204 in the same manner as load lock 234 of FIG. 2A.

Prior to the delayering process, the user may cause the processor to activate the vacuum pump 232 to vacuumize chamber 204. Once vacuumized, the delayering process begins by the user or processor activating ion beam source 210 to generate ion beam 212 thus starting the delayering of IC 208 positioned on rotatable and tiltable support structure 206. The delayering process ends when an etchant signal is detected signaling to the processor that the delayering should stop. After the completion of the delayering process based on reception of an etchant signal, and prior to the imaging of IC 208, support structure 206 is rotated in the direction shown by arrow 209 so that now delayered upper surface of IC 208 directly faces imaging tool 203 to allow the process of imaging delayered IC 208 to occur. Once imaging is completed, the now delayered and imaged IC 208 may be removed from chamber 204 via load lock 234. It is noted that the rotation of movable support structure 206 may be performed autonomously, for example with the aid of optical image recognition, machine vision, artificial intelligence (AI), computer control signals or other imaging techniques, or it may be performed manually by a user.

IC evaluation apparatus of FIG. 3A operates in a similar manner to the apparatus of FIG. 3, but with a different architecture than that of the IC evaluation apparatus of FIG. 3. Referring to FIG. 3A, chamber 204 has two side openings (not shown): a first side attached to load lock 234 as previously discussed. Chamber 204 has a second opening (not shown) for attaching SEM column 216, and lens and apertures housing 218 to the other side of chamber 204 with lens and apertures 218 positioned within chamber 204 as shown. An optional isolation valve 239 may be positioned between SEM column 216 and chamber 204 as shown. A single baffle or a series of baffes or pinholes (not shown) may be created at the isolation valve 239 to maintain the imaging system at several orders of magnitude of lower pressure than chamber 204.

By way of illustration only and without restriction, FIG. 3A conceptually depicts at least a portion of an exemplary IC evaluation apparatus that integrates delayering and imaging functionalities according to one or more aspects of the invention. The ion beam source 210 is mounted at the top of vacuumizable chamber 204 and generates a highly directional ion beam 212 directed towards and focused on an upper surface of the IC chip 208 disposed on movable support structure 206. The ion beam 212 is used to physically remove material from the IC chip 208. In one or more aspects of the invention, an inert gas is introduced to the ion beam source 210 to form the ion beam 212, which moves directionally towards the surface of the IC chip 208 with relatively high energy. The ions then strike the surface of the IC 208 and the resulting impact removes, or sputters, material from the IC chip 208. This method of etching provides high accuracy and precision through the control of the ion beam energy by the ion beam source 210.

Continuing with the description of the IC evaluation apparatus of FIG. 3A, chamber 204 has two openings—a bottom opening and a side opening (not shown). The side opening may be attached to load lock 234 as previously discussed. Chamber 204 has a bottom opening (not shown) for attaching SEM column 216, and lens and apertures housing 218 to the bottom of chamber 204 with lens and apertures 218 positioned within chamber 204 as shown. An optional isolation valve 239 may be positioned between SEM column 216 and chamber 204 as shown. A single baffle or a series of baffes or pinholes (not shown) may be created at the isolation valve 239 to maintain the imaging system at several orders of magnitude of lower pressure than chamber 204.

A high vacuum pump 228 is coupled to a side of chamber 204 via an opening (not shown). The high vacuum pump 228 may be a cryogenic pump or a turbomolecular pump. The high vacuum pump 228 may be mounted at the side (at an opening—not shown), top, or bottom of chamber 204. An optional isolation valve 230 is positioned between high vacuum pump 228 and chamber 204. Load lock 234 is coupled to one side of chamber 204 in the same manner as in FIG. 3 as previously discussed.

After the completion of the delayering process and prior to the imaging of IC 208, movable support structure 206 is rotated in the direction shown by arrow 209 so that now delayered IC 208 directly faces imaging tool 203 to allow the process of imaging now delayered IC chip 208 to occur. The now delayered and imaged IC chip 208 may be removed from chamber 204 via load lock 234. It is noted that the rotation of movable support structure 206 may be performed autonomously, for example with the aid of optical image recognition, machine vision, artificial intelligence (AI), computer control signals or other imaging techniques, or it may be performed manually by a user.

IC evaluation apparatus of FIG. 3A operates in a similar manner to the apparatus of FIG. 3, but with a different architecture than that of the IC evaluation apparatus of FIG. 3. Referring to FIG. 3A, chamber 204 has two side openings (not shown): a first side may be attached to load lock 234 to a side of chamber 204 as previously discussed. Chamber 204 has a second opening (not shown) for attaching SEM column 216, and lens and apertures housing 218 to the other side of chamber 204 with lens and apertures 218 positioned within chamber 204 as shown. An optional isolation valve 239 may be positioned between SEM column 216 and chamber 204 as shown. A single baffle or a series of baffes or pinholes (not shown) may be created at the isolation valve 239 to maintain the imaging system at several orders of magnitude of lower pressure than chamber 204.

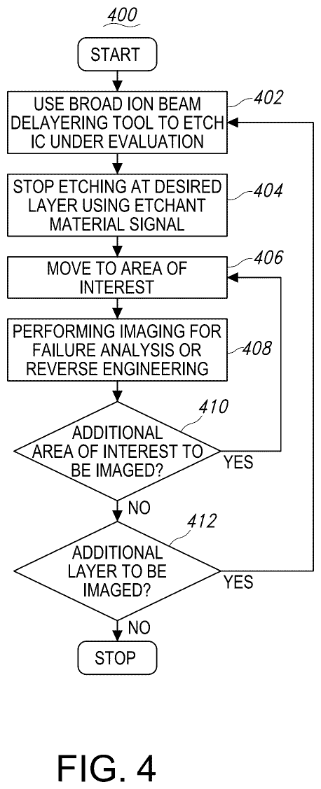

FIG. 4 is a flow diagram depicting at least a portion of an exemplary method 400 for performing IC evaluation, according to one or more aspects of the present invention. An IC evaluation apparatus of the present invention uses method 400 depicted by the flow chart of FIG. 4, which starts at step 402, and may include obtaining an IC sample (device or wafer) to be evaluated. Step 402 may also include prescribed setup and initialization procedures for the IC delayering tool and imaging tool (e.g., alignment of the IC sample on the support structures of the IC delayering and imaging tools, adjusting the resolution, focus, or other parameters of the imaging tool, and adjusting one or more parameters of the IC delayering tool, etc.). As discussed supra, an IC evaluation apparatus (see FIGS. 2, 2A, 3, and 3A) is used to evaluate an IC to determine whether said IC has any defects. It is again noted that the terms “delayering” and “etching” are used interchangeably and are understood to have the same meaning.

At step 402, the IC evaluation apparatus of the present invention uses its etching tool to perform etching of the IC sample under evaluation. At some point during the etching process, the IC evaluation apparatus (examples of which are depicted in FIGS. 2, 2A, 3, and 3A) will receive a signal from an etching monitoring device such as an Optical Emission Spectrometer (OES) or a Secondary Ion Mass Spectrometry (SIMS) (which are in communication with the IC evaluation apparatus) indicating that the etching should stop as the desired layer or etch depth has been reached. At step 404, the etching is stopped based on the etchant signal received by the IC evaluation apparatus.

At step 406, the IC evaluation apparatus transfers or moves or otherwise prepares for imaging the IC under evaluation. Step 406 can include actions that are required for imaging such as changing the vacuum level or opening or closing valves, which may be performed automatically or manually. At step 408 the IC evaluation apparatus activates its imaging tool for failure analysis or reverse engineering, at the first area of interest. At step 410, if there are any other areas of interest that have not been examined, the method of the present invention moves to step 406 where the area(s) of interest(s) left are examined iteratively between steps 410 and 406 until all areas of interest left are examined. The method of the present invention then moves to step 412 where it determines whether there are any other layers of the IC under evaluation that have not yet been examined. If there exists other layers to be examined, then the method of the present invention moves back to step 402 to continue the iterative process described above until there are no more areas of interest to examine and no more IC layers to examine.

Methodologies according to aspects of the present disclosure may take the form of an entirely hardware aspect or combining hardware and software aspects that may all generally be referred to herein as an “apparatus,” “module” or “system.” Furthermore, aspects of the present disclosure, or portions thereof, may take the form of a computer program product embodied in one or more computer readable medium(s) having computer readable program code stored thereon. For example, such computer readable program code may be used in conjunction with an IC evaluation system comprising delayering and imaging functionalities according to some aspects of the invention to control one or more aspects of the system (e.g., etching depth, IC chip positioning, image focusing or resolution, etc.).

Any combination of one or more computer-usable or computer-readable medium(s) may be utilized. The computer-usable or computer-readable medium may be a computer-readable storage medium. A computer-readable storage medium may be, for example but not limited to, an electronic, magnetic, optical, electromagnetic, infrared, or semiconductor system, apparatus, device, or any suitable combination of the foregoing. More specific examples (a non-exhaustive list) of the computer-readable storage medium would include the following: a portable computer diskette, a hard disk, a random access memory (RAM), a read-only memory (ROM), an erasable programmable read-only memory (EPROM or flash memory), an optical fiber, a portable compact disc read-only memory (CD-ROM), an optical storage device, a magnetic storage device, or any suitable combination of the foregoing. In the context of this disclosure, a computer-readable storage medium may be any non-transitory medium that can contain or store a program for use by or in connection with an instruction execution system, apparatus or device.

Computer program code for carrying out operations of aspects of the present disclosure may be written in any combination of one or more programming languages, including an object oriented programming language such as Java, Smalltalk, C++ or the like, and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described herein with reference to methods, apparatus (systems) and computer program products. It will be understood that some of the methods, apparatus and computer program products according to aspects of the invention may be implemented using individual functional modules, blocks and/or circuits, and that combinations of such modules, blocks and/or circuits, may be implemented at least in part by computer program instructions running (i.e., executing) on one or more processing devices.

These computer program instructions may be stored in a non-transient computer-readable medium that can direct a computer or other programmable data processing apparatus or processor to function in a particular manner, such that the instructions stored in the computer-readable medium produce an article of manufacture including instruction means which implement a prescribed function/act according to one or more aspects of the invention.

The illustrations of aspects of the present invention described herein are intended to provide a general understanding of the various aspects, and are not intended to serve as a complete description of all the elements and features of apparatus, systems and methods that might make use of the techniques described herein. Many other aspects will become apparent to those skilled in the art given the teachings herein; other aspects are utilized and derived therefrom, such that structural and logical substitutions and changes can be made without departing from the spirit and scope of this disclosure. The drawings are also merely representational and may not be drawn to scale. Accordingly, the specification and drawings are to be regarded in an illustrative rather than a restrictive sense.

Aspects of the invention are referred to herein, individually and/or collectively, by the term “aspect” merely for convenience and without intending to limit the scope of this application to any single aspect or inventive concept if more than one is, in fact, shown. Thus, although specific aspects have been illustrated and described herein, it should be understood that an arrangement achieving the same purpose can be substituted for the specific aspect(s) shown; that is, this disclosure is intended to cover any and all adaptations or variations of various aspects. Combinations of the above aspects, and other aspects not specifically described herein, will become apparent to those of skill in the art given the teachings herein.

The terminology used herein is for the purpose of describing particular aspects only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Relational terms such as “upper,” “lower,” “above,” “below,” “front” and “back,” when/if used, are intended to indicate relative positioning of elements or structures to each other when such elements are oriented in a particular manner, as opposed to defining an absolute position of the elements.

The corresponding structures, materials, acts, and equivalents of all means or step-plus-function elements in the claims below are intended to include any structure, material, or act for performing the function in combination with other claimed elements as specifically claimed. The description of the various aspects has been presented for purposes of illustration and description, but is not intended to be exhaustive or limited to the forms disclosed. Many modifications and variations will be apparent to those of ordinary skill in the art without departing from the scope and spirit of the invention. The aspects were chosen and described in order to best explain the principles of the invention and the practical application, and to enable others of ordinary skill in the art to understand the various aspects with various modifications as are suited to the particular use contemplated.

The abstract is provided to comply with 37 C.F.R. § 1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single aspect for the purpose of streamlining the disclosure. This method of disclosure is not to be interpreted as reflecting an intention that the claimed aspects require more features than are expressly recited in each claim. Rather, as the appended claims reflect, inventive subject matter lies in less than all features of a single aspect. Thus the following claims are hereby incorporated into the Detailed Description, with each claim standing on its own as separately claimed subject matter.

Given the teachings of aspects of the invention provided herein, one of ordinary skill in the art will be able to contemplate other implementations and applications of the techniques of aspects of the invention. Although illustrative aspects of the invention have been described herein with reference to the accompanying drawings, it is to be understood that aspects of the invention are not limited to those precise aspects, and that various other changes and modifications are made therein by one skilled in the art without departing from the scope of the invention, as manifested in the accompanying claims.

1. An apportioned integrated circuit chip evaluation apparatus comprising:
a vacuumizable chamber having a first portion, a second portion and a third portion and each portion having at least a top surface, a bottom surface, and side surfaces;
an etching tool coupled to the top surface of the first portion of the vacuumizable chamber;
an imaging tool coupled to the top surface of the second portion of the vacuumizable chamber;
a transport mechanism disposed at least partly in the first, second and third portions of the vacuumizable chamber including a first movable support structure disposed in the first portion of the vacuumizable chamber, and a second movable support structure disposed in the second portion of the vacuumizable chamber, and whereby a first vacuum pump is coupled to the first chamber portion and a second vacuum pump is coupled to the second chamber portion;
a processor coupled to the etching tool, the imaging tool, the transport mechanism, the first and second vacuum pumps, and a non-transitory processor readable storage medium containing program code for operations to be performed by the processor;
whereby after an IC chip is disposed in the first portion of the vacuumizable chamber and positioned on the first movable support structure, the processor vacuumizes the chamber and operates the etching tool to etch the IC chip and upon the apparatus receiving a signal to stop the etching process, the processor deactivates the etching tool to stop the etching process followed by the processor operating the transport mechanism to transfer the etched IC chip to the second portion of the vacuumizable chamber and activate the imaging tool to perform imaging on the etched IC chip as desired without breaking vacuum.

2. The apparatus of claim 1 wherein the etching tool includes an ion beam source coupled to the processor and positioned at the top surface of the first chamber portion over a shutter covering an opening at the top surface, whereby the shutter is coupled to the processor such that when the ion beam source is activated by the processor, the ion beam source generates an ion beam passing through the shutter and the opening to impinge on the IC chip placed on the movable support structure of the transport mechanism thus etching the IC chip.

3. The apparatus of claim 1 wherein the imaging tool includes a Scanning Electron Microscope (SEM) column mounted at the top surface of the second chamber portion and positioned over an opening to allow a housing, containing lenses and apertures, and extending from the SEM column, to be disposed in the second chamber portion above the support structure of the transport mechanism on which an IC to be imaged is positioned and fastened.

4. The apparatus of claim 3 wherein the IC to be imaged is fastened using one or more of electrostatic mechanisms, clamping mechanisms, or adhesives.

5. The apparatus of claim 1 wherein a load lock is coupled over an opening at a side surface of the first chamber portion for quick loading of the IC chip without venting the chamber.

6. The apparatus of claim 1 wherein the first vacuum pump is mounted at an opening at the bottom surface of the first chamber portion.

7. The apparatus of claim 1 wherein the second vacuum pump is mounted at an opening at the bottom surface of the second chamber portion.

8. The apparatus of claim 1 wherein the imaging tool includes an SEM column mounted on top of the second chamber portion over an opening with the SEM column having a housing extending therefrom whereby such housing contains a series of lenses and apertures.

9. The apparatus of claim 8 wherein the housing extending from the SEM column and containing a series of lenses and apertures, extends through the opening and is disposed in the second chamber portion directly above the support structure of the second chamber portion to allow a focused electron beam emanating from the housing to image an IC chip positioned on and fastened to a support structure of the transport mechanism.

10. The apparatus of claim 1 wherein the processor is coupled to the first vacuum pump and to the second vacuum pump and vacuumizes the vacuumizable chamber by operating the vacuum pumps attached to the first and second chamber portions.

11. The apparatus of claim 1 wherein the support structure may have any combination of the following:
(a) heating with heating elements, bulbs, or hot water;
(b) cooling with water, Helium gas or other gas;
(c) tiltable relative to the ion beam during etching so as to control etch rate.

12. A single chamber integrated circuit chip evaluation apparatus comprising:
a vacuumizable chamber having a top opening, a bottom opening and side openings;
an integrated circuit chip etching tool mounted over the top opening of the chamber;
an integrated circuit chip imaging tool mounted over a side opening of the chamber;
a high vacuum pump mounted over the bottom opening of the chamber;
a rotatable and tiltable substrate holder disposed in the chamber and positioned to receive ion beams emanating from the etching tool; and
a processor coupled to the etching tool, the imaging tool, the high vacuum pump, the substrate holder and a non-transitory processor readable storage medium containing processor readable program code for operations to be performed by the processor whereby after the integrated circuit chip is fastened onto the substrate holder positioned directly beneath the ion beam etching tool, the processor operates the high vacuum pump to vacuumize the chamber and operates the etching tool to perform etching of the integrated circuit chip and upon the apparatus receiving an etching signal to stop etching, the processor operates the imaging tool to perform imaging of the etched integrated circuit chip without breaking vacuum.

13. The apparatus of claim 12 wherein a shutter is positioned over the top opening at the top surface of the vacuumizable chamber and underneath the ion beam source.

14. A method of evaluating an Integrated Circuit chip, the method comprising the steps of:
a.) using a Broad Ion Beam delayering tool to etch an IC under evaluation in a vacuumized chamber;
b.) stopping the etching at a desired layer based on receipt of an etchant material signal; and
c.) performing imaging of the etched IC in an area of interest to determine if any damage has occurred or for reverse engineering;
wherein the all steps are conducted without breaking the vacuum in the vacuumized chamber.
